(19) United States
(12) Patent Application Publication
(10) Pub. No.: US 2017/0276771 A1
(43) Pub. Date: Sep. 28, 2017

(54) METHOD FOR CONTROLLING LASER RADAR DEVICE AND LASER LIGHT-EMITTING CIRCUIT

(71) Applicant: FUJITSU LIMITED, Kawasaki-shi (JP)

(72) Inventors: Kazunori Hayami, Fukuoka (JP); Koichi Iida, Kobe (JP)

(73) Assignee: FUJITSU LIMITED, Kawasaki-shi (JP)

(21) Appl. No.: 15/415,488

(22) Filed: Jan. 25, 2017

(30) Foreign Application Priority Data
Mar. 28, 2016 (JP) 2016-063531

(51) Int. Cl. G01S 7/484; H01S 5/026; G01S 7/486; G01S 17/10; G01S 7/481

(52) U.S. Cl. CPC G01S 7/484; G01S 17/10; G01S 7/4817; G01S 7/4865; H01S 5/0261

(57) ABSTRACT

A method for controlling a laser radar device, the method includes: closing a first switch configured to open or close a power supply circuit including a laser element; applying a voltage in a forward direction to the laser element; illuminating an object with an electromagnetic wave emitted from the laser element; applying, to the laser element, a voltage in a reverse direction that is opposite to the forward direction when the first switch is opened; detecting a reflected wave from the object; and measuring a location of the object.

### CROSS-REFERENCE TO RELATED APPLICATION

This application is based upon and claims the benefit of priority of the prior Japanese Patent Application No. 2016-063531, filed on Mar. 28, 2016, the entire contents of which are incorporated herein by reference.

### FIELD

The embodiment discussed herein is related to a method for controlling a laser radar device and laser light-emitting circuit.

### BACKGROUND

Based on high-speed pulse currents supplied by a drive circuit, the drive circuit causes a semiconductor laser to emit pulsed laser light or electromagnetic waves.

The related art is disclosed in Japanese Laid-open Patent Publication No. 2001-237489, Japanese Laid-open Patent Publication No. 03-225982, or Japanese Laid-open Patent Publication No. 05-190949.

### SUMMARY

According to an aspect of the embodiments, a method for controlling a laser radar device, the method includes: closing a first switch configured to open or close a power supply circuit including a laser element; applying a voltage in a forward direction to the laser element; illuminating an object with an electromagnetic wave emitted from the laser element; applying, to the laser element, a voltage in a reverse direction that is opposite to the forward direction when the first switch is opened; detecting a reflected wave from the object; and measuring a location of the object.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a laser radar device;

FIG. 2 illustrates an example of the relationship between the reflection time period of laser light and the distance to an object;

FIG. 3 illustrates an example of a laser radar light device;

FIG. 4 illustrates an example of a light-emitting circuit;

FIG. 5A to FIG. 5E illustrate an example of states for laser light;

FIG. 6 illustrates an example of a light-emitting circuit;

FIG. 7 illustrates an example of a light-emitting circuit;

FIG. 8 illustrates an example of a light-emitting circuit;

FIG. 9 illustrates an example of a light-emitting circuit;

FIG. 10 illustrates an example of a light-emitting circuit;

FIG. 11A to FIG. 11F illustrate an example of states for laser light; and

FIG. 12 illustrates an example of a method for controlling a laser radar device.

### DESCRIPTION OF EMBODIMENT

For example, the turn-on or turn-off state of a current that is supplied to a laser element is controlled by a drive circuit, and therefore illumination with pulsed electromagnetic waves (for example, pulse light) having a very short pulse width associated with the illumination time is performed. Such a laser drive circuit is applied to a laser radar device (LIDAR device), a millimeter wave radar device, an optical communication device, a laser printer, an optical drive reader/writer, a laser processing device, or the like.

The theoretical pulse width in pulsed electromagnetic waves is associated with a power supply time period of a laser element. For example, variations in current waveform lag behind opening and closing of a power supply circuit and, as a result, a current including “rounding” is supplied to the laser element. Therefore, the pulse width is likely to be large relative to the power supply time period. For example, a dummy load is arranged in a circuit coupled parallel to a laser element with respect to a power supply, and switches of both the circuits are driven to be switched in a complementary manner, so that the variations in current waveform are reduced. For example, in the circuit parallel to the laser element, a fixed-voltage element and another laser element having the same impedance are arranged.

For example, in such a circuit structure as described above, current oscillations might occur owing to the influence of a parasitic inductor lying in a laser element. Therefore, it is difficult to reduce a time period over which current is supplied, and thus reduction in pulse width might be not performed. For example, with a laser radar device, the spatial resolution is dependent on the pulse widths of illumination waves and reflected waves. Therefore, it is desirable to reduce the pulse widths in order to improve measurement accuracy. For example, a damping resistor is arranged in series to the laser element in order to reduce current oscillations due to the parasitic inductor. In this case, the loss caused by the damping resistor might increase.

For example, the pulse widths of electromagnetic waves may be reduced.

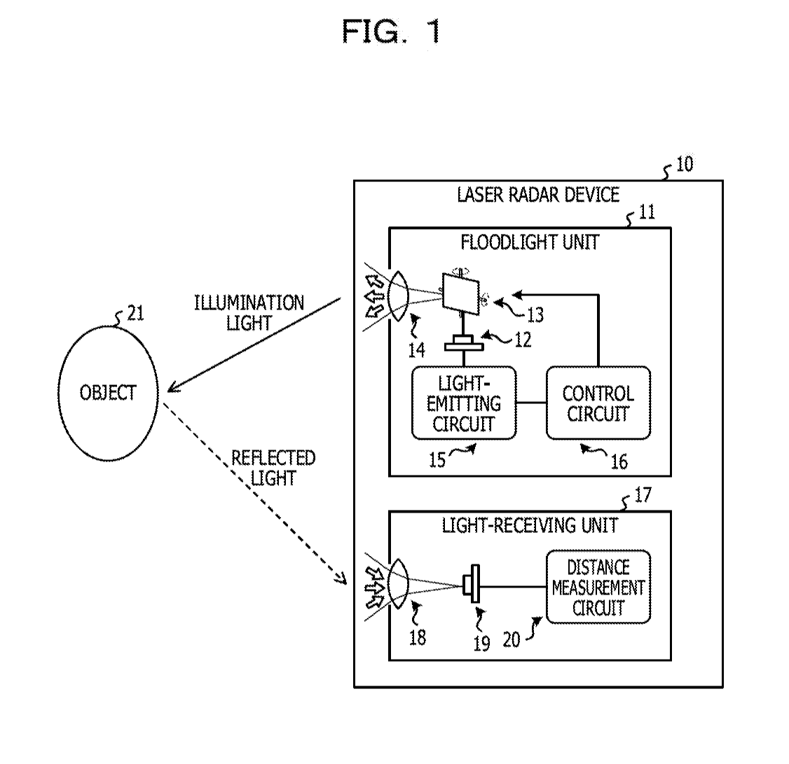

FIG. 1 illustrates an example of a laser radar device. A laser radar device 10 illustrated in FIG. 1 detects reflected light of light emitted by a laser device 12, which is the source of electromagnetic waves, to measure the location of an object 21 that has reflected the electromagnetic waves. The laser radar device 10 may be a distance-measuring device that handles a vehicle, a walker, an obstacle, or the like around the distance-measuring device as the object 21, and may be mounted, for example, on a vehicle. The laser radar device 10 is provided with a floodlight unit 11 for floodlighting with illumination light, and a light-receiving unit 17 that receives reflected light. The laser device 12, a scanning mirror 13, a lens 14, a light-emitting circuit 15 (drive circuit), and a control circuit 16 are provided inside the floodlight unit 11.

The laser device 12 may be a semiconductor laser that provides stimulated emission of laser light, and may be, for example, a can-shaped package of a semiconductor laser that emits near-infrared light with a central wavelength of about 700 to 1000 nm. For example, the peak output (peak power) of the laser device 12 may range from at least several watts to several tens of watts or more. The width of pulse light (pulse width) may be of the order of several hundred nanoseconds or less, for example, from several nanoseconds to several tens of nanoseconds.

The laser device 12 emits large-output laser light compared with a light-emitting device for communication (optical communication laser device). For example, in an optical communication laser device, the bias current and the modulating current of a drive circuit are about several tens of milliamperes; however, in the laser device 12 illustrated in FIG. 1, the bias current and the modulating current of a drive circuit are several tens of amperes. Therefore, in the laser device 12, the amount of stored energy with parasitic inductance components might be large, or the influences exerted on the pulse width of laser light by parasitic inductance components might be large. Even parasitic inductance components that are negligible for a laser device for communication might be at a level that is not negligible for the laser radar device 10. Parasitic inductance components may lie in bonding wires or signal pins integrated in the laser device 12, patterns between a drive circuit and a laser diode element (LD element), or the like.

The scanning mirror 13 may be a reflecting device such as a micro electro mechanical system (MEMS) mirror, a galvanometer mirror, or a polygon mirror. The illumination light is emitted through the lens 14 toward the outside of the laser radar device 10 after the optical path (illumination direction) has been changed with the scanning mirror 13. Therefore, the scanning range of the illumination light is enlarged to exceed the limitations resulting from the movable range of the scanning mirror 13. The light-emitting circuit 15 controls a current that is supplied to the laser device 12, and the control circuit 16 controls the power supply state of the light-emitting circuit 15 and the operating state of the scanning mirror 13. The control circuit 16 has functionality of controlling switching (the turn-on or turn-off state of power supply) of the light-emitting circuit 15.

A light-receiving lens 18, a light-receiving element 19, and a distance measurement circuit 20 are provided inside the light-receiving unit 17. Of illumination light emitted from the lens 14, light (reflected light) reflected by the object 21 is made to converge on the surface of the light-receiving element 19 through the light-receiving lens 18. The light-receiving element 19 may be a photo-diode that outputs an electric signal in accordance with the intensity of light. The distance measurement circuit 20 measures a distance D from output of the light-receiving element 19 to the object 21.

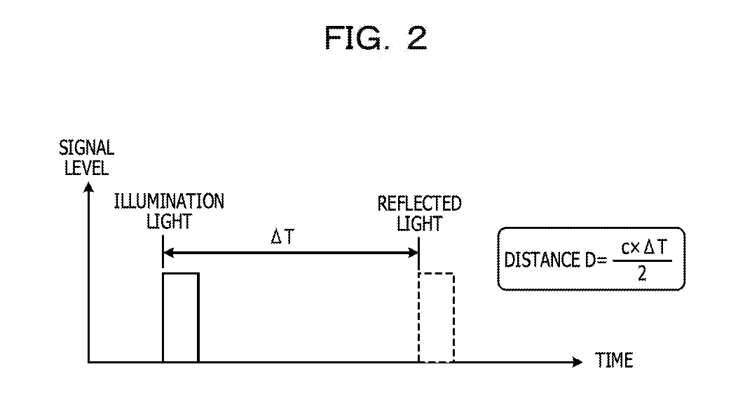

FIG. 2 illustrates an example of the relationship between the reflection time period of laser light and the distance to an object. As illustrated in FIG. 2, the distance D to the object 21 has a value obtained by dividing the product of a time period ΔT until the reflected light of laser light arrives at the light-receiving element 19 after the laser light has been emitted and a light speed c by two. The smaller the pulse width of the illumination light or the reflected light, the higher the spatial resolution. The larger the slope of the rising edge or the falling edge of pulse light, for example, the steeper the slope of variations in signal level, the higher the accuracy in identifying a time point at which reflected light is detected.

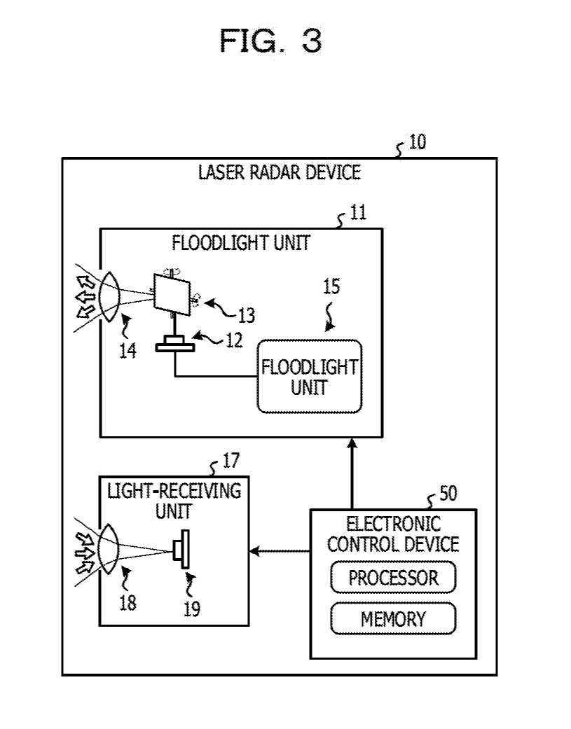

Each of the control circuit 16 and the distance measurement circuit 20 may be implemented by hardware (an electronic circuit) or may be implemented in part or in whole by software. FIG. 3 illustrates an example of a laser radar device. For example, when the circuit is implemented by software, as illustrated in FIG. 3, an electronic control device 50, for example, a computer is integrated in the laser radar device 10. The electronic control device 50 controls the scanning mirror 13 and the light-emitting circuit 15 and may have arithmetic processing functionality for measuring the distance D.

A processor, memory, an interface device, or the like is integrated in the electronic control device 50. The processor may be a processing device in which, for example, a control unit (control circuit) and an arithmetic unit (arithmetic circuit), cache memory (resistor), and the like are integrated. The memory may be a storage device in which programs and data that is being worked are stored, and includes read only memory (ROM), random access memory (RAM), nonvolatile memory, or the like. The details of control that is performed in the electronic control device 50 are recoded and stored as firmware and application programs in the memory. At the time of execution of a program, the content of the program is loaded into memory space and is executed by the processor.

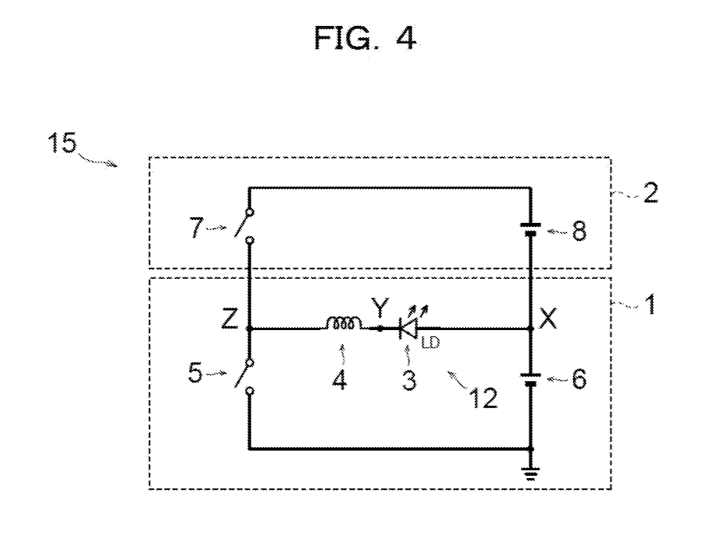

FIG. 4 illustrates an example of a light-emitting circuit. In the light-emitting circuit 15 illustrated in FIG. 4, a power supply circuit 1 and a release circuit 2 are provided. The power supply circuit 1 supplies power for light emission of the laser device 12. The laser device 12 including a laser element 3 (laser chip) and a parasitic inductor (parasitic inductance component) 4, a first switch 5, and a first power supply 6 are arranged in the power supply circuit 1. In the power supply circuit 1, a voltage in the forward direction V₁ is applied to the laser device 12. The first power supply 6 may be a power supply whose supply voltage is variable or may be a power supply whose supply voltage is fixed. When the first power supply 6 is a power supply with a variable supply voltage, the supply voltage may be controlled by the electronic control device 50.

The release circuit 2 releases the energy stored in the parasitic inductor 4 by applying, to the laser element 3, a voltage (reverse voltage) in the reverse direction that is opposite to the direction in which a voltage is applied in the power supply circuit 1. The release circuit 2 may be coupled parallel to the laser device 12. For example, the “reverse direction” may be the reverse direction assuming that the orientation of a voltage in the rise time period of a current is set as the forward direction. The duration during which the reverse voltage is applied may be at least within the fall time period of a current.

A second switch 7 and a second power supply 8 are arranged in the release circuit 2. The second power supply 8 is disposed in the release circuit 2 so as to apply, to the laser device 12, a voltage V₂ in the reverse direction that is opposite to the direction in which a voltage is applied by the first power supply 6. For example, in the release circuit 2, a voltage in the reverse direction (a voltage having a value with the reversed sign) is applied to the laser device 12. The second power supply 8 may be a power supply whose supply voltage is variable or may be a power supply whose supply voltage is fixed. When the second power supply 8 is a power supply with a variable supply voltage, the supply voltage may be controlled by the electronic control device 50.

The first switch 5 or the second switch 7 may include a switch circuit of a transistor (bipolar transistor), a field effect transistor (FET), or the like. The first switch 5 is driven so as to be intermittently closed (turned on) with a given period corresponding to the illumination period of illumination light. The duration during which the first switch 5 is closed (a first turn-on time period T₁) corresponds to a duration (rise time period) during which a current flowing through the laser element 3 of the laser device 12 rises until the current reaches a given amount, for example, a duration during which a given amount of current continues to be supplied. When the first switch 5 is turned on, the laser element 3 emits light, and energy is stored in the parasitic inductor 4. Thereafter, when the first switch 5 is turned off, the light emission of the laser element 3 stops, and the energy stored in the parasitic inductor 4 gradually decreases.

The second switch 7 is closed in the fall time period of a current flowing through the laser device 12. For example, the second switch 7 is closed under the condition where at least the first switch 5 is once closed and then is opened. The duration during which the second switch 7 is closed (a second turn-on time period T₂) may be set so as to correspond to a duration in which the energy stored in the parasitic inductor 4 is completely released. For example, when the voltage (absolute value) of the first power supply 6 and the voltage (absolute value) of the second power supply 8 are approximately the same, the first turn-on time period T₁ and the second turn-on time period T₂ may be set to be approximately the same. When the voltage (absolute value) of the first power supply 6 and the voltage (absolute value) of the second power supply 8 are different, the operating state of the second switch 7 is controlled so that the product of the voltage (absolute value) of the first power supply 6 and the first turn-on time period T₁ approximately matches the product of the voltage (absolute value) of the second power supply 8 and the second turn-on time period T₂.

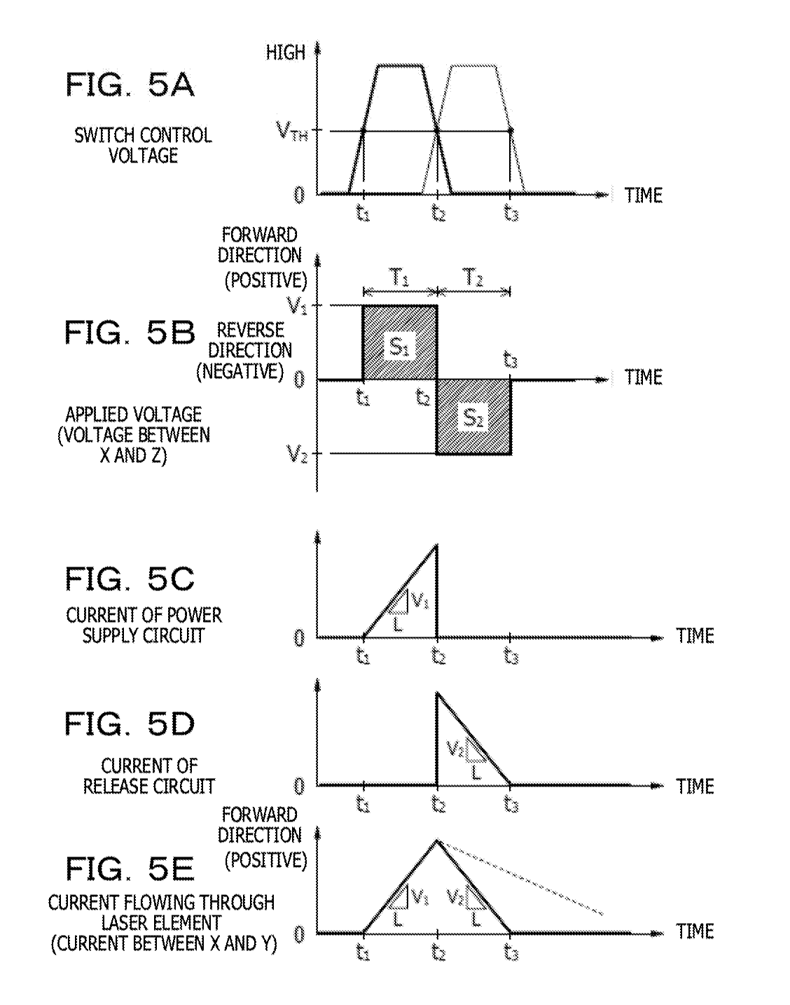

FIG. 5A to FIG. 5E illustrate an example of states for laser light. In a graph of a switch control voltage illustrated in FIG. 5A, a bold solid line denotes a control voltage for the first switch 5, and a thin solid line denotes a control voltage for the second switch 7. The time period from a time point t₁ to a time point t₂ during which the control voltage for the first switch 5 is greater than or equal to a given value V_{TH} may correspond to a time period during which the voltage between X and Z is in the forward direction, for example, the first turn-on time period T₁ illustrated in FIG. 5B. Likewise, the time period from the time point t₂ to a time point t₃ during which the control voltage for the second switch 7 is greater than or equal to the given value V_{TH} may correspond to a time period during which the voltage between X and Z is in the reverse direction, for example, the second turn-on time period T₂ illustrated in FIG. 5B.

Each of the voltage V₂ of the second power supply 8 and the second turn-on time period T₂ may be set so that an area S₂ corresponding to the product of a voltage absolute value |V₂| of the second power supply 8 and the second turn-on time period T₂ is approximately the same as an area S₁ corresponding to the product of the voltage absolute value |V₁| of the first power supply 6 and the first turn-on time period T₁. The second turn-on time period T₂ does not necessarily have to be started at the end time point of the first turn-on time period T₁. For example, settings may be made so that the second turn-on time period T₂ starts slightly later than the end time point of the first turn-on time period T₁.

As illustrated in FIG. 5C, the current of the power supply circuit gradually ascends during the first turn-on time period T₁. The slope of changes in current value (time rate of change) is proportional to the value obtained by dividing the voltage V₁ of the first power supply 6 by a self-inductance L of the parasitic inductor 4. The current of the release circuit gradually descends during the second turn-on time period T₂ as illustrated in FIG. 5D. The slope of changes in current value is proportional to the value obtained by dividing the voltage V₂ of the second power supply 8 by the self-inductance L. The energy stored in the parasitic inductor 4 during the first turn-on time period T₁ is actively extracted during the second turn-on time period T₂. Therefore, voltage and current oscillations due to the remaining energy and their variation delays might be reduced.

For example, the pulse shape of a current flowing through the laser element 3 (current between X and Y) is triangular as represented by the solid line in FIG. 5E. For example, when the voltage V₁ of the first power supply 6 and the voltage V₂ of the second power supply 8 are approximately the same, the absolute values of the slopes of changes in current value are approximately the same between the first turn-on time period T₁ and the second turn-on time period T₂. Therefore, the pulse shape of illumination light emitted from the laser device 12 is a shape symmetrical in the time direction about the time point t₂.

For example, if the release circuit 2 is not provided, the energy stored in the parasitic inductor 4 remains in the power supply circuit 1 for a long time. Therefore, as represented by the broken line in FIG. 5E, the current flowing through the laser element 3 does not quickly decrease at and after the time point t₂, resulting in a distorted pulse shape. In contrast, providing the release circuit 2 leads to applying voltages in opposite directions in the fall time period and the rise time period of a current, and thus the pulse width of a current flowing through the laser element 3 is reduced. Therefore, the pulse width of laser light might also be reduced.

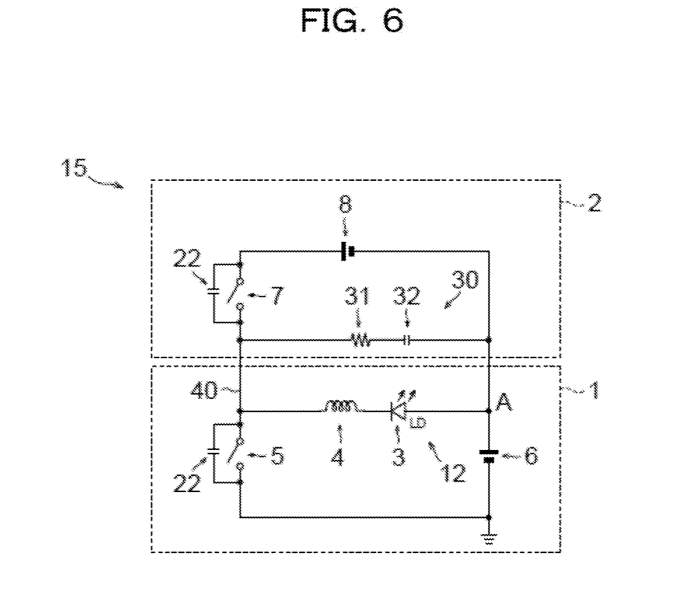

FIG. 6 illustrates an example of a light-emitting circuit. In FIG. 6, a damping circuit 30 is added to the light-emitting circuit 15 illustrated in FIG. 4. The damping circuit 30 suppresses voltage oscillations and current oscillations occurring while the second switch 7 is closed, and may be arranged in the release circuit 2. In FIG. 6, the damping circuit 30 is formed so as to couple the portion located upstream of the laser device 12 with the portion located downstream of the laser device 12 in the release circuit 2. The damping circuit 30 may be a circuit parallel to the laser device 12. A damping resistor 31 and a capacitor 32 are arranged in the damping circuit 30, and thus a snubber circuit is formed.

Voltage oscillations and current oscillations are able to occur, for example, when FETs are used for the first switch 5 and the second switch 7. This is because there are parasitic capacitances called gate input capacitors 22 (Ciss) between the sources and the drains of FETs. Upon completion of the first turn-on time period T₁, the gate input capacitors 22 cause the energy stored in the parasitic inductor 4 to remain within a section (a remaining section 40) sandwiched among the first switch 5, the second switch 7, and the laser device 12. Therefore, the voltage value and the current value in the remaining section 40 oscillate for a long time.

For example, the damping circuit 30 is arranged in the release circuit 2, and thereby the energy stored in the parasitic inductor 4 is consumed by the damping resistor 31 and is converted into heat energy. Therefore, the voltage oscillations or current oscillations after completion of the first turn-on time period T₁ might be reduced to stabilize the voltage value or the current value of the remaining section 40 in a relatively short time period. The capacitor 32 may be omitted.

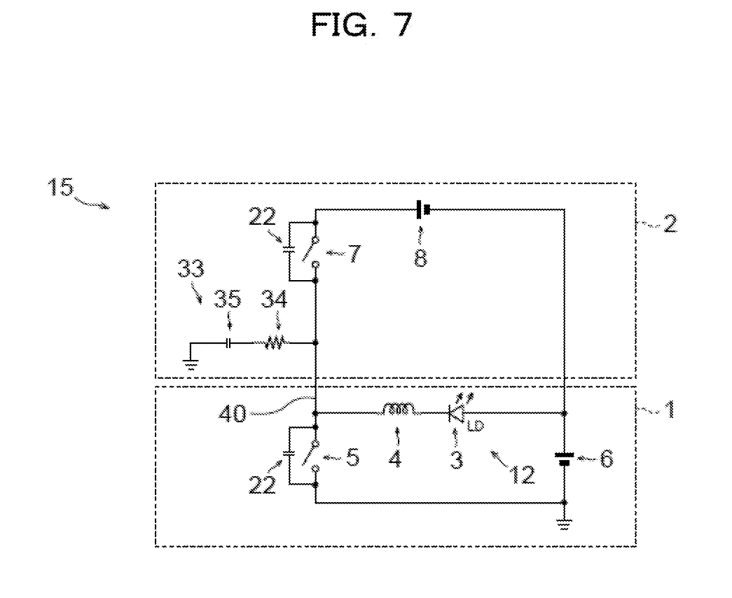

FIG. 7 illustrates an example of a light-emitting circuit. In FIG. 7, a circuit structure in which the damping circuit 33 is formed from the remaining section 40 to the ground (GND) is illustrated. The damping circuit 33 illustrated in FIG. 7, like the damping circuit 30 illustrated in FIG. 6, is disposed parallel to the laser device 12. A dumping resistor 34 and a capacitor 35 are arranged in the damping circuit 33. The energy remaining in the remaining section 40 is consumed by the damping resistor 34 and is converted into heat energy. Therefore, the voltage oscillations or current oscillations after completion of the first turn-on time period T₁ might be suppressed. For example, the capacitor 35 may be omitted.

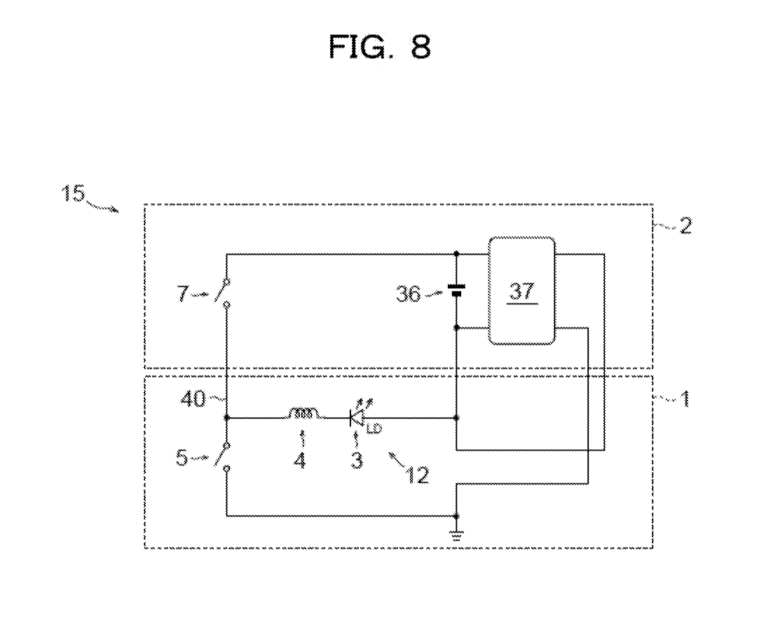

FIG. 8 illustrates an example of a light-emitting circuit. In FIG. 8, a power supply 36 common to the power supply circuit 1 and the release circuit 2 illustrated in FIG. 4 is used. The common power supply 36 is arranged in one of the power supply circuit 1 and the release circuit 2. Power is supplied via a DC-DC converter 37 (transformer) to the other circuit. In this way, with the use of the common power supply 36, the energy stored in the parasitic inductor 4 might be restored to the common power supply 36, and thus the entire power consumption might be reduced.

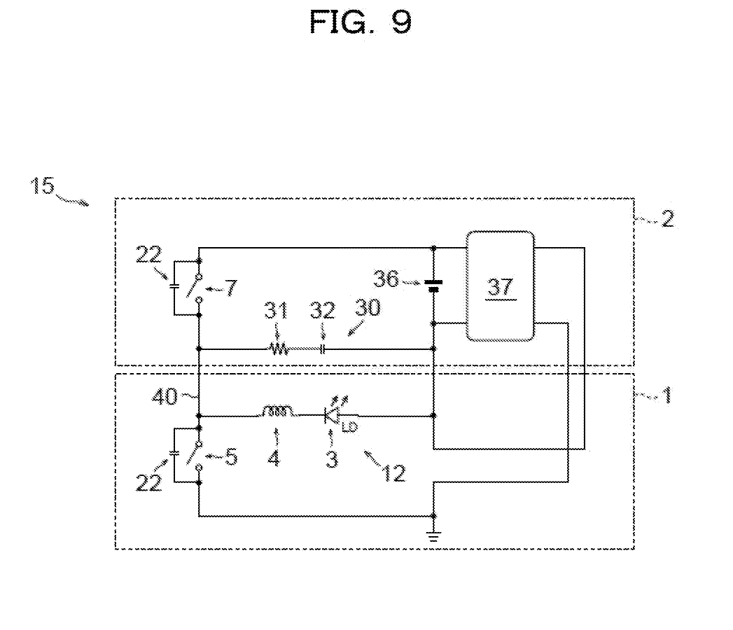

FIG. 9 illustrates an example of a light-emitting circuit. In FIG. 9, the power supply 36 common to the power supply circuit 1 and the release circuit 2 illustrated in FIG. 6 is used. The damping circuit 30 is formed so as to couple the remaining section 40 with the common power supply 36. The damping resistor 31 and the capacitor 32 are arranged in the damping circuit 30. In this way, by combining the common power supply 36 with the damping circuit 30, the energy stored in the parasitic inductor 4 might be returned and might be consumed in the damping circuit 31.

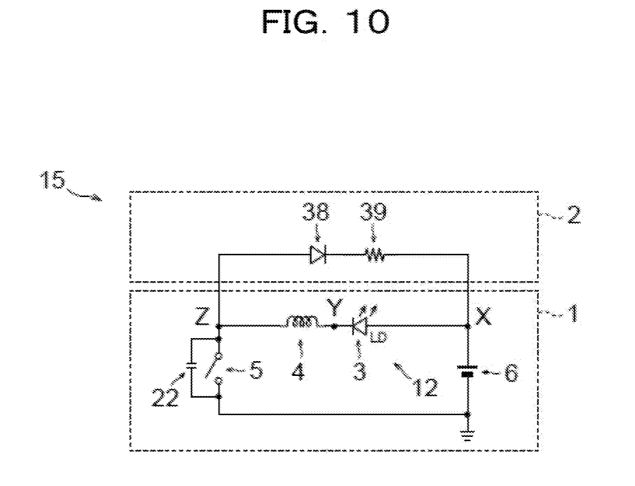

FIG. 10 illustrates an example of a light-emitting circuit. In FIG. 10, the energy stored in the parasitic inductor 4 is released by making use of voltage oscillations or current oscillations that are able to occur in the remaining section 40 immediately after the first switch 5 illustrated in FIG. 4 is opened. Not the second switch 7 but, instead, a diode 38 and an oscillation damping resistor 39 are arranged in the release circuit 2. The diode 38 reduces voltage oscillations or current oscillations by regulating the flowing direction of remaining charges. The resistance of the oscillation damping resistor 39 may be set to have such a magnitude that the current stored in the parasitic inductor 4 decreases to 0 A in a duration during which the voltage of a point Z is positive, for example, in the fall time period of a current flowing through the laser element 3.

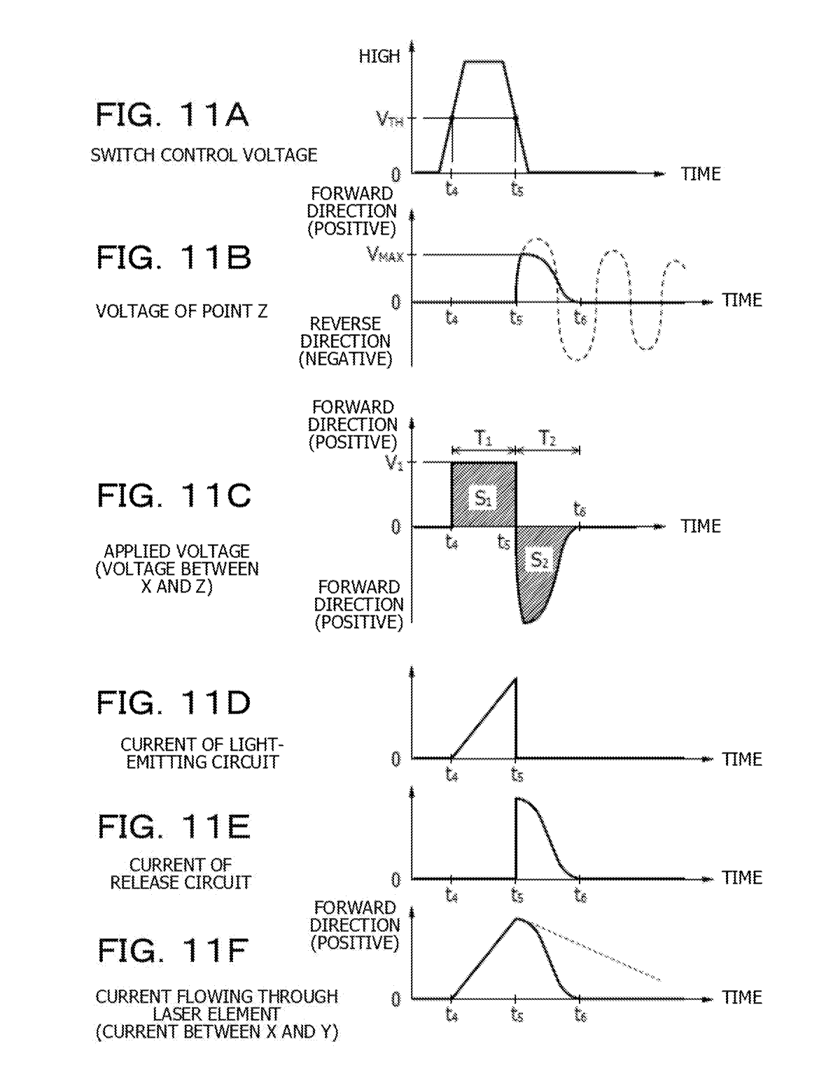

FIG. 11A to FIG. 11F illustrate an example of states for laser light. As illustrated in FIG. 11A, the time period from a time point t₄ to a time point t₅ during which the control voltage for the first switch 5 is greater than or equal to the given value V_{TH} is a duration during which the first switch 5 is closed (the first turn-on time period T₁). Once the first switch 5 is released at the time point t₅, voltage oscillations or current oscillations represented by the broken line in FIG. 11B are able to occur owing to the energy stored in the parasitic inductor 4. The diode 38 and the oscillation damping resistor 39 are arranged in the release circuit 2, and thereby the overshoot of a voltage at the point Z is restricted and the voltage oscillations or current oscillations are reduced. The resistance of the oscillation damping resistor 39 may be set, as illustrated in FIG. 11C, so that an area S₁ corresponding to the time integral of the forward-direction voltage between X and Z approximately matches an area S₂ corresponding to the time integral of the reverse-direction voltage between X and Z.

As illustrated in FIG. 11D, the current of the power supply circuit gradually increases during the first turn-on time period T₁. The current of the release circuit decreases until a time point t₆ at which the current value converges to 0 A, as illustrated in FIG. 11E. As a result, the pulse shape of a current flowing through the laser element 3 (current between X and Y) is triangular as represented by the solid line in FIG. 11F, and the pulse width of laser light is reduced. The energy stored in the parasitic inductor 4 of the laser device 12 is consumed by the oscillation damping resistor 39 and is converted into heat energy. Some of the energy stored in the parasitic inductor 4 and the parasitic capacitance might be restored to the first power supply 6, and thus the entire power consumption might be reduced. If the release circuit 2 is not provided, the energy stored in the parasitic inductor 4 remains in the power supply circuit for a long time. Therefore, as represented by the broken line in FIG. 11F, the current flowing through the laser element 3 at and after a time point t₅ might not quickly decrease, and the pulse width might increase.

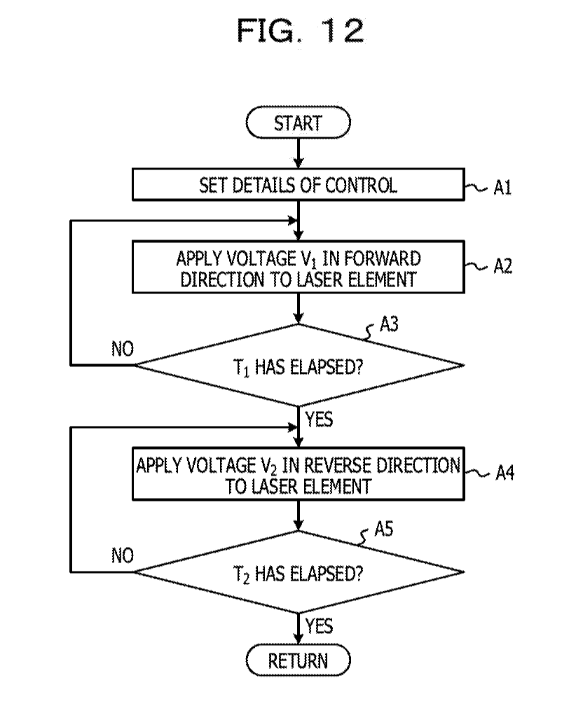

FIG. 12 illustrates an example of a method for controlling a laser radar device. For example, the operating state of any of the light-emitting circuits 15 illustrated in FIG. 4 and FIG. 6 to FIG. 9 is controlled by the electronic control device 50. The control targets are the first switch 5 of the power supply circuit 1 and the second switch 7 of the release circuit 2. When control is performed so as to cause the laser device 12 to emit light, the voltage V₁ in the forward direction, the voltage V₂ in the reverse direction, the first turn-on time period T₁, and the second turn-on time period T₂ are set (operation A1). These parameters may be fixed values set in advance or may be variable values that are variable in accordance with control conditions.

For example, the voltage V₂ of the second power supply 8 or the second turn-on time period T₂ may be set so that the product of the voltage absolute value |V₂| of the second power supply 8 and the second turn-on time period T₂ is approximately equal to the product of the voltage absolute value |V₁| of the first power supply 6 and the first turn-on time period T₁. For example, the voltage V₂ of the second power supply 8 may be set to be a voltage that is approximately equal to the voltage V₁ of the first power supply 6, and the second turn-on time period T₂ may be set to be a time period that is approximately equal to the first turn-on time period T₁. For example, the second turn-n time period T₂ may be set based on the voltage V₁ of the first power supply 6, the voltage V₂ of the second power supply 8, and the first turn-on time period T₁.

The first switch 5 is closed, and the voltage V₁ in the forward direction is applied to the laser element 3 (operation A2). The rise time over which a current flowing through the laser element 3 gradually increases starts. The closed state of the first switch 5 continues until the first turn-on time period T₁ has elapsed (operation A3). Once the first turn-on time period T₁ has elapsed, the first switch 5 is released, and the second switch 7 is closed (operation A4). At this point, a voltage is applied to the laser element 3 in the reverse direction that is opposite to the direction in the rise time period of the current, so that the energy stored in the parasitic inductor 4 is released.

The energy stored in the parasitic inductor 4 might be quickly released, the pulse width of the current flowing through the laser element 3 might be reduced, and the pulse width of laser light might be reduced. The closed state of the second switch 7 continues until the second turn-on time period T₂ has elapsed (operation A5). Once the second turn-on time period T₂ has elapsed, the second switch 7 is opened. Thereafter, the first switch 5 and the second switch 7 are maintained in the closed state until the next light emission timing. Such a control may be repeatedly performed each time the laser device 12 is caused to emit light.

For example, in the laser radar device 10 including the light emission circuit 15, a voltage in the forward direction is applied from the power supply circuit 1 coupled to the laser element 3, and thus pulse light is emitted. Thereafter, in the fall time period of the current, a voltage in the reverse direction is applied from the release circuit 2, and thus the stored energy of the parasitic inductor 4 is quickly released. In this way, the stored energy of the parasitic inductor 4 that increases with emission of pulse light is actively extracted. The falling of the current might be completed in a short time, and thus the light emission pulse width of the laser element 3 might be reduced. Therefore, the accuracy in measuring the object 21 might improve.

For example, in a small-output laser device for communication, in order to decrease parasitic inductance components, the current path between terminals is reduced, and the laser chip is joined to the drive circuit by soldering without the use of wires. For example, in the laser radar device 10 described above, the light-emission pulse width is reduced regardless of the level of the parasitic inductance components, and the parasitic inductance components do not have to be changed. Therefore, in the laser device 12 with a packaging structure in which it is difficult to reduce parasitic inductance components, high-output laser driving with a narrow pulse width might be performed.

For example, as illustrated in FIG. 5B, when the areas S₁ and S₂ are the same, the application of a reverse voltage is completed at the time at which all of the energy stored in the parasitic inductor 4 has been released. Therefore, as illustrated in FIG. 5E, no current in the reverse direction flows to the laser element 3, and thus the protective property of the laser element 3 might improve.

For example, when the voltage V₁ of the first power supply 6 and the voltage V₂ of the second power supply 8 are set to be approximately the same voltage, and when the first turn-on time period T₁ and the second turn-on time period T₂ are set to be approximately the same time period, the light emission pulse shape is a shape symmetrical in the time direction about the time point t₂. Therefore, the absolute value of the rise slope and the absolute value of the fall slope of pulse light are approximately the same, and changes at the signal level might be obtained with good accuracy. The accuracy in identifying a time point at which reflected light is detected might improve, and the accuracy in measuring the object 21 might improve.

For example, in any of light-emitting circuits illustrated in FIG. 4 and FIG. 6 to FIG. 9, the first switch 5 is arranged in the power supply circuit 1, and the second switch 7 is arranged in the release circuit 2. The second switch 7 is closed at least while the first switch 5 is open. By controlling the closed and open states of the two switches 5 and 6, the direction in which a voltage is applied is changed to the forward direction or to the reverse direction with a simple circuit configuration. Adjustment of the first turn-on time period T₁ and the second turn-on time period T₂ might be made easier, and thus the light-emission pulse width of the laser element 3 might be reduced with high precision.

For example, in the light-emitting circuit illustrated in FIG. 6, FIG. 7, or FIG. 9, the damping circuit 30, 33 is added for suppressing voltage oscillations or current oscillations occurring while the second switch 7 is closed. In the damping circuit 30, 33, the damping resistor 31, 34 and the capacitor 32, 35 are arranged. Coupling the damping circuit 30, 33 to the remaining section 40 in such a manner might lead to quick release of the energy stored in the parasitic inductor 4 without causing oscillations. Therefore, the voltage oscillations or current oscillations after completion of the first turn-on time period T₁ might be reduced, and thus the light-emission pulse width of the laser element 3 might be controlled with good accuracy.

For example, in the light-emitting circuit illustrated in FIG. 8 or FIG. 9, the power supply circuit 1 and the release circuit 2 receive power supply from the single common power supply 36 to operate. In this way, making the power supply 36 common to the power supply circuit 1 and the release circuit 2 simplifies the device configuration, and the energy stored in the parasitic inductor 4 might be restored to the power supply 36 to improve the energy efficiency. Voltages whose absolute values are approximately the same are easily applied to the power supply circuit 1 and the release circuit 2, and therefore the first turn-on time period T₁ and the second time period T₂ are set to be approximately the same. Therefore, a light-emitting pulse having a shape symmetrical in the time direction about the time point t₂ might be generated, and thus the accuracy in measuring the object 21 might improve.

For example, the common power supply 36 may be arranged in one of the power supply circuit 1 and the release circuit 2 and is coupled to the other via the DC-DC converter 37. With such a configuration structure, the voltage V₁ of the power supply circuit 1 and the voltage V₂ of the release circuit 2 are easily changed. Therefore, all of the energy stored in the parasitic inductor 4 might be released with good accuracy and be restored.

For example, in the light-emitting circuit illustrated in FIG. 10, the diode 38 and the oscillation damping resistor 39 are arranged, and the stored energy of the parasitic inductor 4 is released by making use of voltage oscillations or current oscillations in the remaining section 40. For example, a reverse voltage in the fall time period is applied to the laser element 3 by making use of the rebound of remaining charges. The magnitude of the reverse voltage is restricted by the resistance of the oscillation damping resistor 39. Therefore, setting a suitable resistance leads to accurately releasing or restoring the stored energy of the parasitic inductor 4.

In the laser radar device 10, the floodlight unit 11 and the light-receiving unit 17 may be separated or may be integrated together. When they are integrated together, for example, a half mirror may be arranged on the optical path so that reflected light that has entered the laser radar device 10 is reflected toward the light-receiving element 19 by a half mirror. For example, after illumination light emitted from the laser device 12 is reflected by a half mirror, the illumination light may be projected to the scanning mirror 13. By integrating together the floodlight unit 11 and the light-receiving unit 17, the lens 14 and the light-receiving lens 18 are unified. Accordingly, while the device configuration is simplified, advantages substantially the same as in the case where the floodlight unit 11 and the light-receiving unit 17 are separated might be obtained.

The application object of the light-emitting circuit 15 is not limited only to the laser radar device 10. For example, the light-emitting circuit 15 described above may be applied to a laser printer, an optical drive reader/writer, a laser processing device, or the like. By employing a circuit structure as that of the light-emitting circuit 15 described above, advantages as discussed above might be obtained, and thus the pulse width of the laser element 3 might be reduced.

The circuit structures illustrated in FIG. 4 and FIG. 6 to FIG. 10 may be appropriately combined. For example, the common power supply 36 and the DC-DC converter 37 in FIG. 8 may be applied to the circuit structure of a third embodiment illustrated in FIG. 7. The diode 38 and the oscillation damping resistor 39 in FIG. 10 may be applied to the release circuit 2 in any of FIG. 4 and FIG. 6 to FIG. 9.

Light emitted by driving of the circuit described above is not limited to near-infrared light of the laser device 12. For example, a scheme of using electromagnetic waves in a millimeter wave band, instead of near-infrared light, may be employed. The light-emitting circuit 15 described above may be applied to a millimeter-wave radar device. Since light is a kind of electromagnetic waves, the words such as “light, light emission, illumination light, and reflected light” described above may be replaced with words such as “electromagnetic waves, illumination with electromagnetic waves, illumination electromagnetic waves, and reflected waves”.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method for controlling a laser radar device, the method comprising:
closing a first switch configured to open or close a power supply circuit including a laser element;
applying a voltage in a forward direction to the laser element;
illuminating an object with an electromagnetic wave emitted from the laser element;
applying, to the laser element, a voltage in a reverse direction that is opposite to the forward direction when the first switch is opened;
detecting a reflected wave from the object; and
measuring a location of the object.

2. The method according to claim 1, wherein energy stored in a parasitic inductor of the laser element is released by the applying of the voltage in the reverse direction.

3. The method according to claim 1, wherein the applying of the voltage in the reverse direction is performed in a fall time period of a current.

4. The method according to claim 1, wherein a magnitude of a product of the voltage in the reverse direction and a time period of the applying of the voltage in the reverse direction is substantially equal to a magnitude of a product of the voltage in the forward direction and a time period of the applying of the voltage in the forward direction.

5. The method according to claim 1, wherein a magnitude of the voltage in the forward direction and a time period of the applying of the voltage in the forward direction are substantially equal to a magnitude of the voltage in the reverse direction and a time period of the applying of the voltage in the reverse direction, respectively.

6. The method according to claim 2, wherein the energy is released by closing a second switch configured to open or close a release circuit disposed together with the power supply circuit, in a fall time period of a current that is produced when the first switch is opened.

7. The method according to claim 6, wherein a voltage oscillation while the second switch is closed is reduced with a damping circuit coupled parallel to the laser element.

8. The method according to claim 6, wherein a power supply common to the power supply circuit and the release circuit is provided.

9. The method according to claim 8, wherein the power supply is arranged in one of the power supply circuit and the release circuit and is coupled via a transformer to the other of the power supply circuit and the release circuit.

10. The method according to claim 6, wherein the release circuit includes:
a diode disposed so as to couple a lower potential side when a voltage in the forward direction is applied to the laser element with a power supply, and configured to rectify a direction of a current to a direction from the lower potential side toward the power supply in the release circuit; and
a resistor configured to convert the energy to heat.

11. A laser light-emitting circuit comprising:
a laser element including a parasitic inductor;
a power supply circuit configured to apply a voltage in a forward direction to the laser element so as to cause the laser element to emit light;
a power supply configured to supply power to the power supply circuit;
a first switch arranged in the power supply circuit; and
a release circuit configured to apply, to the laser element, a voltage in a reverse direction that is opposite to the forward direction while the first switch is open.

12. The laser light-emitting circuit according to claim 11, wherein energy stored in the parasitic inductor is released by the applying of the voltage in the reverse direction.

13. The laser light-emitting circuit according to claim 11, wherein the applying of the voltage in the reverse direction is performed in a fall time period of a current.

14. The laser light-emitting circuit according to claim 11, wherein a magnitude of a product of the voltage in the reverse direction and a time period of the applying of the voltage in the reverse direction is substantially equal to a magnitude of a product of the voltage in the forward direction and a time period of the applying of the voltage in the forward direction.

15. The laser light-emitting circuit method according to claim 11, wherein a magnitude of the voltage in the forward direction and a time period of the applying of the voltage in the forward direction are substantially equal to a magnitude of the voltage in the reverse direction and a time period of the applying of the voltage in the reverse direction, respectively.

16. The laser light-emitting circuit according to claim 11, further comprising:
a release circuit configured to release energy stored in the parasitic inductor by closing a second switch which is disposed together with the power supply circuit and open or close the release circuit in a fall time period of a current that is produced when the first switch is opened.

17. The laser light-emitting circuit according to claim 16, wherein a voltage oscillation while the second switch is closed is reduced with a damping circuit coupled parallel to the laser element.

18. The laser light-emitting circuit according to claim 16, wherein a power supply common to the power supply circuit and the release circuit is provided.

19. The laser light-emitting circuit according to claim 18, wherein the power supply is arranged in one of the power supply circuit and the release circuit and is coupled via a transformer to the other of the power supply circuit and the release circuit.

20. The laser light-emitting circuit according to claim 16, wherein the release circuit includes:
a diode disposed so as to couple a lower potential side when a voltage in the forward direction is applied to the laser element with a power supply, and configured to rectify a direction of a current to a direction from the lower potential side toward the power supply in the release circuit; and
a resistor configured to convert the energy to heat.
